(19) United States
(12) Patent Application Publication
(10) Pub. No.: US 2026/0247912 A1
(43) Pub. Date: Aug. 20, 2026

(54) WAFER TRANSPORTATION CONTAINER

(71) Applicant: TAIWAN SEMICONDUCTOR MANUFACTURING COMPANY, LTD., Hsinchu (TW)

(72) Inventor: Fung-Chih HUANG, Hsinchu (TW)

(73) Assignee: TAIWAN SEMICONDUCTOR MANUFACTURING COMPANY, LTD., Hsinchu (TW)

(21) Appl. No.: 19/053,821

(22) Filed: Feb. 14, 2025

(51) Int. Cl. H10P 72/10

(52) U.S. Cl. CPC H10P 72/1916

(57) ABSTRACT

A wafer transportation container includes a container body and a door. The container body has an inner space for accommodation of wafers, an opening configured to allow passage of the wafers into or out of the inner space, an inner peripheral edge disposed along a perimeter of the opening, and a first protrusion formed immediately inwardly of the inner peripheral edge. The door is removably coupled to the container body, and includes a door body and a second protrusion. The door body has an outer peripheral edge, and an inward surface for confronting the inner space. The second protrusion is formed on the inward surface. The inward surface has an interconnection region between the second protrusion and the outer peripheral edge of the door body. When the door is coupled to the container body, a gap is formed among the first protrusion, the second protrusion and the interconnection region.

### BACKGROUND

A wafer transportation container is used to transport wafers to different processing tools in semiconductor manufacturing. These containers are designed to safely hold and protect the delicate wafers during transit, preventing contamination or damage. They are made from materials that minimize particle generation and ensure cleanliness, which is critical in semiconductor fabrication. The container's design allows for easy handling and secure transport between various stages of the wafer processing, ensuring that wafers remain in optimal condition. By providing safe and efficient transportation, wafer containers play a vital role in maintaining the quality and yield of semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic perspective view illustrating a wafer transportation container including a container body and a door in accordance with some embodiments.

FIG. 2 is a fragmentary, schematic perspective view illustrating the container body shown in FIG. 1 in accordance with some embodiments.

FIG. 3 is a schematic perspective view illustrating the door shown in FIG. 1 in accordance with some embodiments.

FIG. 4 is a schematic sectional view taken along line A-A of FIG. 1, illustrating the door coupled to the container body in accordance with some embodiments.

FIG. 5 is a fragmentary, schematic sectional view illustrating engagement between the door and the container body shown in FIG. 1 in accordance with some embodiments.

FIGS. 6 to 9 are each a fragmentary, schematic sectional view illustrating a modification of a first protrusion of the container body shown in FIG. 5 in accordance with some embodiments.

FIG. 10 is a fragmentary, schematic perspective view illustrating the container body shown in FIG. 9 in accordance with some embodiments.

FIG. 11 is a schematic perspective view illustrating the door in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” even if the terms “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about,” when used with a value, can capture variations of, in some aspects ± 20%, in some aspects ± 10%, in some aspects ± 5%, in some aspects ± 2.5%, in some aspects ±1%, in some aspects ± 0.5%, and in some aspects ± 0.1% from the specified amount, as such variations are appropriate to perform the disclosed methods or employ the disclosed compositions and could be understood by those skilled in the art after reviewing the present disclosure.

In a semiconductor device production process that involves Chip-on-Wafer-on-Substrate (CoWoS) technology or Integrated Fan-Out (InFO) technology, wafer transportation containers are necessary for transporting semiconductor wafers and/or other types of substrates for forming semiconductor devices on each of the semiconductor wafers and/or the substrates, and are placed on load ports in one of multiple stages of the semiconductor device production process. Each of the wafer transportation containers includes a container body and a door. For each of the wafer transportation containers, the door has to be opened or closed during the semiconductor device production process. The closing of the door is performed using a robotic arm, and is ideally performed when the door and the container body are well aligned with each other and then fittingly coupled to each other. However, it is common that the container body and the door are misaligned. The misalignment of the door and the container body causes failure in closing the door, or failure in locking the door. The load ports include sensors that are capable of detecting whether, in each of the wafer transportation containers, the door is closed, or locked. When any one of the failures is detected by the sensors, the load ports generate alarms, and then the semiconductor device production process is immediately ceased. When the alarms go off frequently, cycle times and potential delays in the semiconductor device production process may be increased. In addition, the misalignment may further cause the door to hit the container body, and impact of the hit may generate particles from abrasion of a surface of any one of the container body and the door. When the particles fall on the semiconductor wafers that are contained in the wafer transportation container, it would undesirably result in a decrease in yield and affect the quality of the final products. Furthermore, it is possible that the door is forced to be locked when the door and the container body are not fittingly coupled to each other due to the misalignment, deviation from a horizontal position, or unexpected movement. When the door is forced to be locked in such a situation, the door or the container body is worn, which results in generation of particles that may fall onto suckers of a wafer transfer arm used for transferring the semiconductor wafers and/or other types of substrates in the semiconductor device production process. The particles on the wafer transfer arm may trigger another alarm that ceases the semiconductor device production process, and the semiconductor device production process may be further delayed. The misalignment may also cause improper wafer transfer, or improper sealing, which causes air leakage, which allows debris, moisture, and/or other types of contaminants from a semiconductor production facility to enter the wafer transportation containers. In some cases, the misalignment may further result in physical damage to the wafer transportation containers or the wafers due to improper contact or uneven pressure during handling, or may break the wafer transportation containers or cause wafer defects (e.g., abrasion, oxidation, and/or other types of defects). These issues may lead to device failures, reduced semiconductor processing yields, increased scrap, higher maintenance costs, and/or increased risk of defects in the final product.

The present disclosure is directed to a wafer transportation container including a container body, and a door that is removably coupled to the container body. The door, when being coupled to the container body, cooperates with the container body to define a gap therebetween. The gap provides a greater tolerance to engagement between the container body and the door, and thus it facilitates the alignment of the door with the container body.

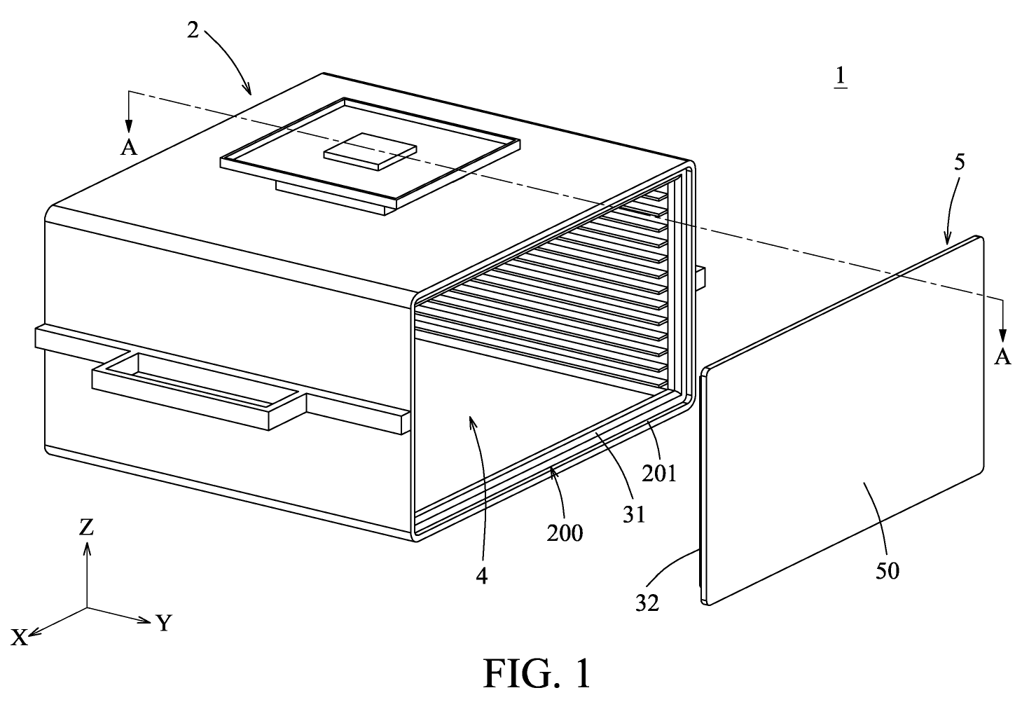

FIG. 1 is a schematic perspective view illustrating a wafer transportation container 1 in accordance with some embodiments. The wafer transportation container 1 is configured to accommodate a plurality of wafers (not shown) and/or other types of substrates (not shown) therein so that the wafers and/or the substrates can be transported throughout various locations of semiconductor processing facility (e.g., load ports, and/or other devices; not shown) during a semiconductor device production process which involves Chip-on-Wafer-on-Substrate (CoWoS) technology or Integrated Fan-Out (InFO) technology. The wafer transportation container 1 may include a wafer cassette, or another type of container that is configured to hold and/or store the semiconductor wafers (not shown) during the semiconductor device production process. It is noted that, for ease of description, the wafers (not shown) and/or other types of the substrates (not shown) will hereinafter be referred to as the semiconductor wafers.

Referring to FIG. 1, the wafer transportation container 1 includes a container body 2 and a door 5. The door 5 is removably coupled to the container body 2. The container body 2 is substantially a cuboid and is hollow for the semiconductor wafers (not shown) to be stored therein, and the door 5 is substantially rectangular to match the shape of the container body 2. In some embodiments, each of the container body 2 and the door 5 may have a shape and/or appearance different from that shown in FIG. 1. Other suitable geometric shapes for each of the container body 2 and the door 5 are within the contemplated scope of the present disclosure.

The container body 2 has a width in an X direction, a length in a Y direction, and a height in a Z direction. The X, Y and Z directions are transversal (e.g., perpendicular) to each other. In some embodiments, a robotic arm (not shown) may carry a handle (not shown) on the door 5, and then move the door 5 along the Y direction so as to couple the door 5 with the container body 2 or remove the door 5 from the container body 2. In addition, after the door 5 is coupled with the container body 2, the door 5 may be locked to the container body 2 using any suitable locking mechanism (not shown) therebetween.

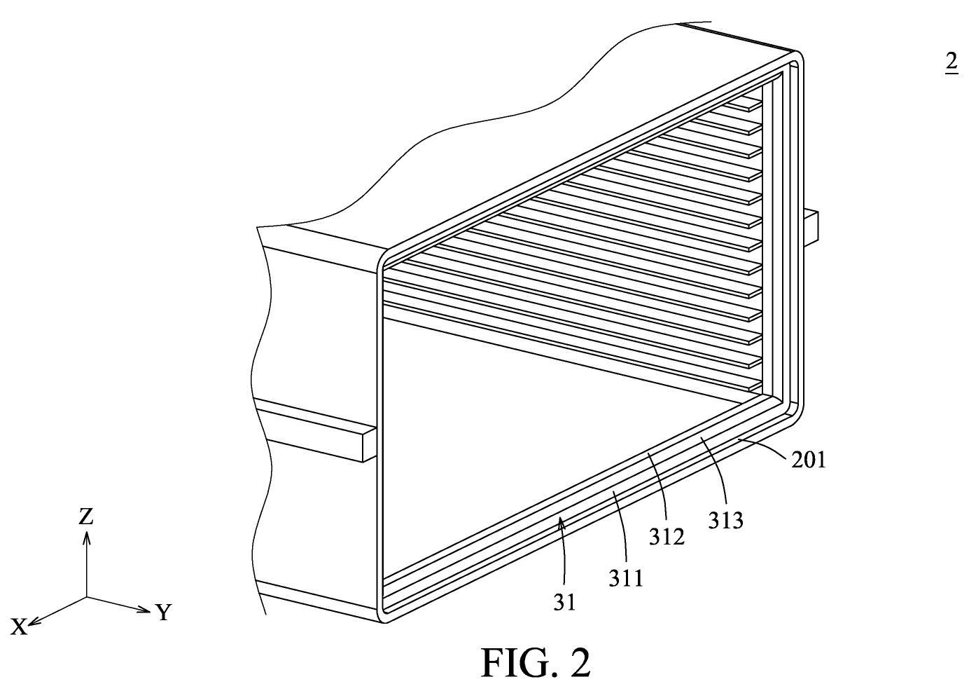

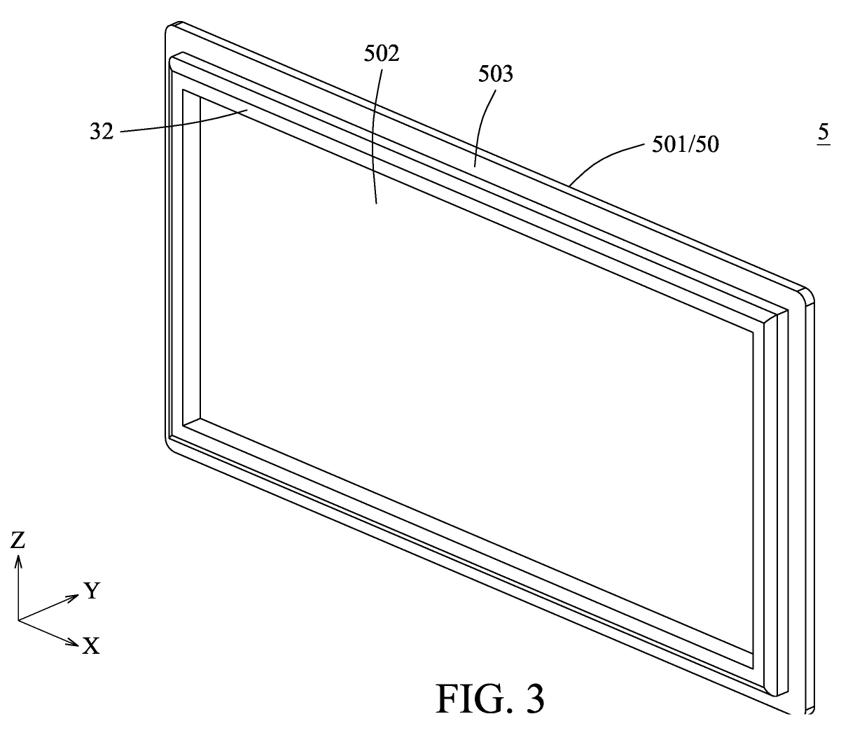

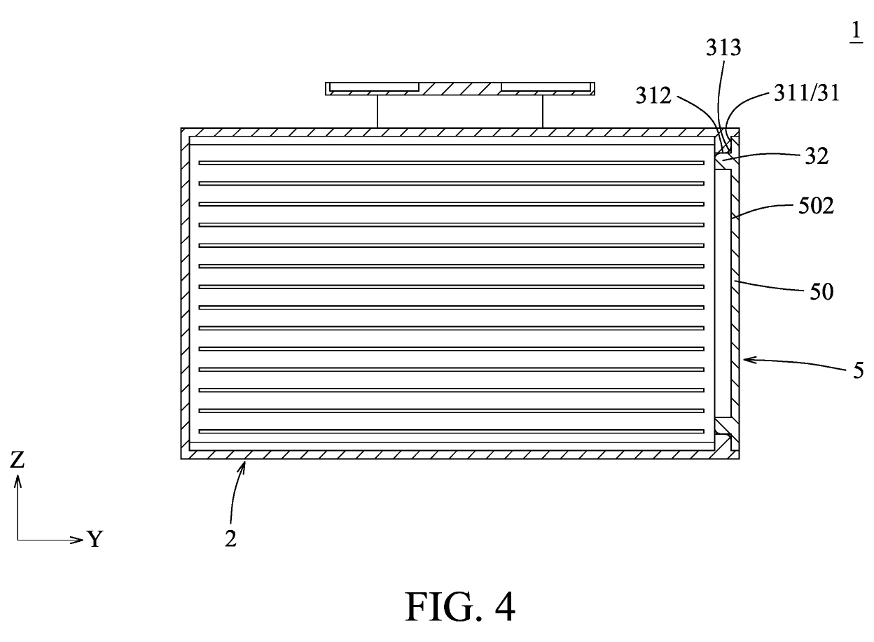

FIG. 2 is a fragmentary, enlarged schematic perspective view illustrating a portion of the container body 2 in accordance with some embodiments. FIG. 3 is a schematic perspective view illustrating the door 5 shown in FIG. 1 in accordance with some embodiments. FIG. 4 is a schematic sectional view taken along line A-A of FIG. 1, illustrating the door 5 coupled to the container body 2 in accordance with some embodiments.

Referring to FIG. 1, the container body 2 has an inner space 4, an opening 200, an inner peripheral edge 201, and a first protrusion 31. The inner space 4 is for accommodation of the semiconductor wafers (not shown). The opening 200 is configured to allow passage of the semiconductor wafers (not shown) into or out of the inner space 4. The inner peripheral edge 201 is disposed along a perimeter of the opening 200. The first protrusion 31 is formed immediately inwardly of the inner peripheral edge 201. Referring to FIGS. 1, 2 and 4, the first protrusion 31 has a first surface 311, a second surface 312 and a third surface 313. The third surface 313 interconnects the first surface 311 and the second surface 312.

Referring to FIGS. 1, 3 and 4, the door 5 includes a door body 50 and a second protrusion 32. The door body 50 has an outer peripheral edge 501, and an inward surface 502 for confronting the inner space 4 of the container body 2. The second protrusion 32 is formed on the inward surface 502 of the door body 50. The inward surface 502 has an interconnection region 503 between the second protrusion 32 and the outer peripheral edge 501 of the door body 50. Referring to FIGS. 1, 2 and 4, the first protrusion 31 of the container body 2 extends along the inner peripheral edge 201 to have a looped shape, and, referring to FIG. 3, the second protrusion 32 of the door 5 extends along the outer peripheral edge 501 to have a looped shape that matches the looped shape of the first protrusion 31 so that the door 5 is operable to be coupled to the container body 2. Other suitable geometric shapes for an extension of the first protrusion 31 on the inner peripheral edge 201, or an extension of the second protrusion 32 on the outer peripheral edge 501 are within the contemplated scope of the present disclosure.

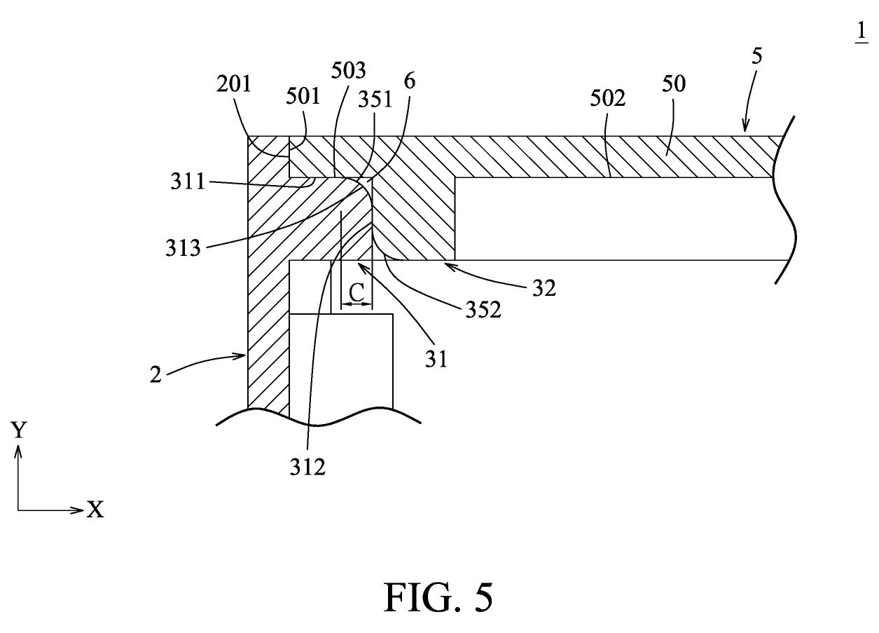

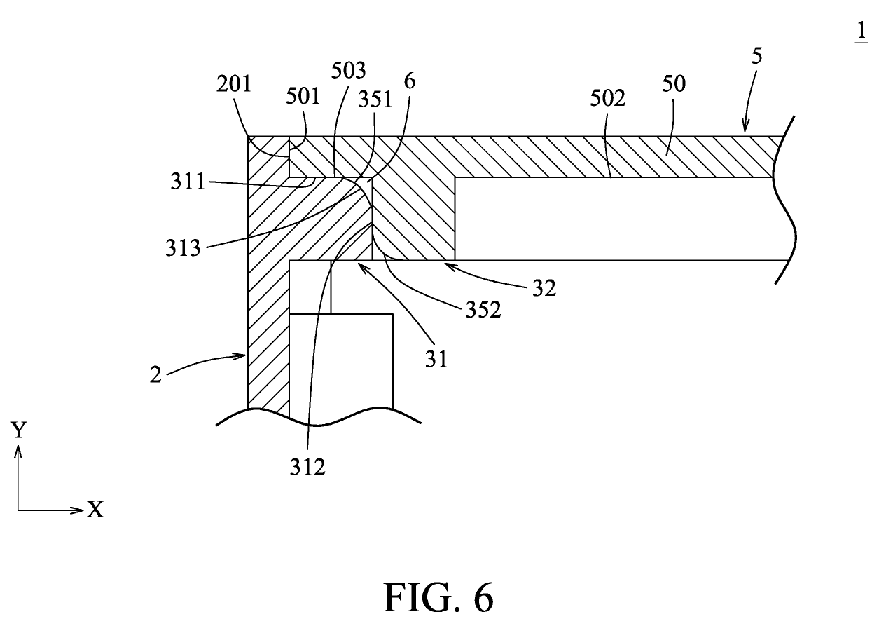

FIG. 5 is a fragmentary, enlarged, schematic sectional view illustrating engagement between the door 5 and the container body 2 when the door 5 is coupled to the container body 2 in accordance with some embodiments. When the door 5 is coupled to the container body 2, the outer peripheral edge 501 of the door body 50 is in sealing engagement with the inner peripheral edge 201 of the container body 2. In some embodiments, the sealing engagement is configured to be air-tight sealing engagement. Other suitable sealing engagements between the door 5 and the container body 2 are within the contemplated scope of the present disclosure. Referring to FIGS. 1 and 3 to 5, when the door 5 is coupled to the container body 2, the first protrusion 31 is in abutting engagement with the interconnection region 503 and the second protrusion 32, and a gap 6 is formed among the first protrusion 31, the second protrusion 32 and the interconnection region 503. The first surface 311 of the first protrusion 31 is configured to confront the interconnection region 503, the second surface 312 of the first protrusion 31 is configured to confront the second protrusion 32, and the third surface 313 of the first protrusion 31 is configured to border the gap 6 when the door 5 is coupled to the container body 2. Referring to FIG. 5, the first surface 311 is in abutting engagement with the interconnection region 503 when the door 5 is coupled to the container body 2, and the third surface 313 is circularly curved. In addition, a radius of curvature (C) of the third surface 313 is greater than about 1 millimeter and not greater than about 10 millimeters. In some other embodiments, referring to FIG. 6, the third surface 313 may be curved but not circularly curved.

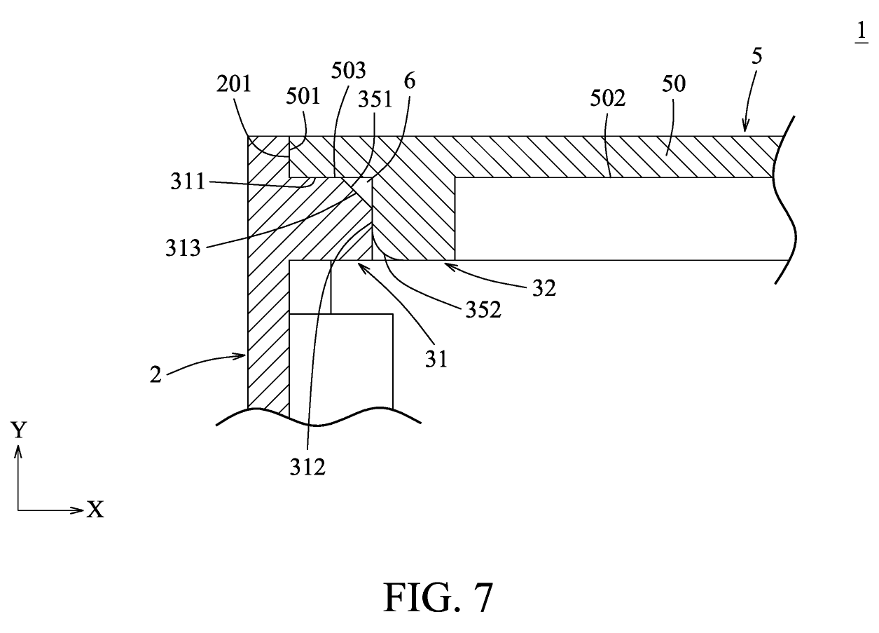

Specifically, the first protrusion 31 has a proximal corner and a distal corner which confront the second protrusion 32. When the door 5 is coupled to the container body 2, the proximal corner and the distal corner are respectively proximal to and distal to the door 5, and the proximal corner confronts a corner between the interconnection region 503 and the second protrusion 32. A first cutout portion 351 is formed on the first protrusion 31 to permit the third surface 313 to be formed as the proximal corner. The proximal corner of the first protrusion 31 may be circularly curved as shown in FIG. 5, may be curved as in the modification of the first protrusion 31 shown in FIG. 6 or as in the modifications of the first protrusion 31 shown in FIGS. 7 to 9 (described hereinafter), or other suitable configurations.

In addition, the second protrusion 32 has a first corner defined with the interconnection region 503, and a second corner opposite to the first corner. A second cutout portion 352 is formed at the second corner and thus the second corner may be curved as shown in FIGS. 5 or 6. When the door 5 is coupled to the container body 2, the first corner and the second corner of the second protrusion 32 confront the first protrusion 31, the first protrusion 31 is in abutting engagement with the second protrusion 32, the proximal corner is spaced apart from the second protrusion 32, and the second corner is spaced apart from the first protrusion 31.

By virtue of the first protrusion 31 having the first cutout portion 351 (i.e., the third surface 313) when the door 5 and the container body 2 are going to be coupled to each other (i.e., when the door 5 is going to be closed) during one of the stages of the semiconductor device production process, tolerance of the engagement between the container body 2 and the door 5 is increased. That is to say, even when the container body 2 and the door 5 are misaligned with each other during movement of the door 5 toward the container body 2, the door 5 is prevented from directly striking the container body 2, thereby preventing failure of closing the door 5. Even if the container body 2 and the door 5 are misaligned and come into contact with each other, the second protrusion 32, especially the second corner of the second protrusion 32, may be guided by the third surface 313 to move along the third surface 313 toward the inner space 4 of the container body 2 (see FIG. 1) such that the container body 2 and the door 5 are fittingly coupled eventually. In addition, by virtue of the first protrusion 31 having the third surface 313, any one of the first protrusion 31 and the second protrusion 32 is prevented from being damaged when the container body 2 and the door 5 are misaligned with each other and hit each other during the movement of the door 5 toward the container body 2. Thus, impact of the hit between the first protrusion 31 and the second protrusion 32 is less likely to result in generation of particles (not shown). As described in the previous paragraph, such particles may fall on the semiconductor wafers (not shown) located inside the inner space 4 or on suckers of a wafer transfer arm. Moreover, with the provision of the third surface 313, especially when the third surface 313 is curved or circularly curved, movement of the second protrusion 32 along the third surface 313 may be smooth. As such, even if there is misalignment therebetween, the door 5 is more liable to fittingly couple with the container body 2 in a way without generating any particles. Consequently, it is less likely to trigger alarm in the semiconductor device production process caused by the misalignment between the container body 2 and the door 5, and the semiconductor device production process may proceed in a more efficient manner.

The curved third surface 313 (i.e., the curved proximal corner) of the first protrusion 31 and the curved second corner of the second protrusion 32 may have configurations to permit the curved second corner to be slidable over the curved proximal corner. In such case, in response to movement of the door 5 toward the container body 2, the curved second corner of the second protrusion 32 is guided by the curved proximal corner of the first protrusion 31. Accordingly, the outer peripheral edge 501 of the door body 50 is brought into sealing engagement with the inner peripheral edge 201 of the container body 2.

A configuration of the first protrusion 31 and/or a configuration of the second protrusion 32 may be modified, or replaced without departure from the spirit and scope of the present disclosure. Several modifications are described hereinafter for serving as some examples. FIG. 7 is a fragmentary, enlarged, schematic sectional view illustrating the engagement between the door 5 and the container body 2 of the wafer transportation container 1 in accordance with some embodiments. The first protrusion 31 shown in FIG. 7 has a structure similar to that of the first protrusion 31 shown in each of FIGS. 5 and 6, but has a difference in the third surface 313. Referring to FIG. 7, in some embodiments, the first cutout portion 351 is also formed on the third surface 313 of the first protrusion 31, but the third surface 313, which is formed as the proximal corner, is a flat surface arranged inclined with respect to both the first surface 311 and the second surface 312 of the first protrusion 31. The proximal corner of the first protrusion 31 is configured to be a truncated corner. When the door 5 is coupled to the container body 2, the truncated first protrusion 31 confronts the first corner of the second protrusion 32 defined between the interconnection region 503 and the second protrusion 32.

By virtue of the first protrusion 31 having the third surface 313, and by virtue of the third surface 313 being inclined with respect to both the first surface 311 and the second surface 312, when the door 5 is going to be closed during one of the stages of the semiconductor device production process, the tolerance of the engagement between the container body 2 and the door 5 is increased. Even if the container body 2 and the door 5 are misaligned and come into contact with each other, the second protrusion 32, especially the second corner of the second protrusion 32, is guided by the flat third surface 313 to move along the third surface 313 toward the inner space 4 of the container body 2 such that the container body 2 and the door 5 are fittingly coupled eventually. In addition, by virtue of the first protrusion 31 having the flat third surface 313 (i.e., the truncated corner), any one of the first protrusion 31 and the second protrusion 32 is prevented from being damaged when the container body 2 and the door 5 are misaligned with each other and hit each other during the movement of the door 5 toward the container body 2. Thus, impact of the hit between the first protrusion 31 and the second protrusion 32 is less likely to generate particles (not shown) from abrasion of the surface of any one of the first protrusion 31 and the second protrusion 32. Moreover, since the curved second corner of the second protrusion 32 may be smoothly guided by the flat third surface 313 to make the door 5 tightly engage with the container body 2, it is less likely to trigger alarm in the semiconductor device production process, and the semiconductor device production process is not liable to be ceased by the misalignment between the container body 2 and the door 5, and may proceed in a more efficient manner.

Similarly, the flat third surface 313 (i.e., the truncated proximal corner) of the first protrusion 31 and the curved second corner of the second protrusion 32 may have configurations to permit the curved second corner to be slidable over the truncated proximal corner. In such case, in response to movement of the door 5 toward the container body 2, the curved second corner of the second protrusion 32 is guided by the flat third surface 313 of the first protrusion 31. Accordingly, the outer peripheral edge 501 of the door body 50 is moved into sealing engagement with the inner peripheral edge 201 of the container body 2. In some embodiments (not shown), the proximal corner of the first protrusion 31 and the second corner of the second protrusion 32 may both be truncated to work well with each other (i.e., the truncated second corner is slidable over the truncated proximal corner).

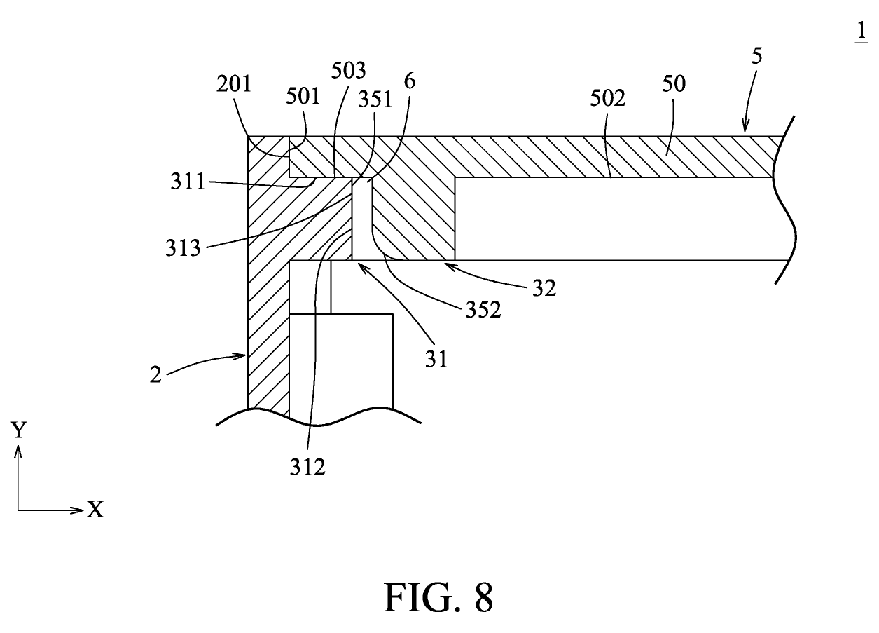

FIG. 8 is a fragmentary, enlarged, schematic sectional view illustrating the engagement between the door 5 and the container body 2 of the wafer transportation container 1 in accordance with some embodiments. The container body 2 shown in FIG. 8 has a structure similar to that of the container body 2 shown in each of FIGS. 5 to 7, but has a difference in the location of the first cutout portion 351 in the first protrusion 31. Referring to FIG. 8, the third surface 313 and the second surface 312 of the first protrusion 31 are coplanar, and the first cutout portion 351 is formed at both the second surface 312 and the third surface 313, and thus the first protrusion 31 has a reduced thickness compared with the first protrusion 31 shown in FIGS. 5 to 7. A thickness of the first protrusion 31 is referred to as a distance between the second surface 312 and a reference plane that is coplanar with the outer peripheral edge 501. When the door 5 is coupled to the container body 2, the first protrusion 31 is spaced apart from the second protrusion 32 by the gap 6 (i.e., each of the second surface 312 and the third surface 313 is spaced apart from the second protrusion 32 by the gap 6). That is to say, when the door 5 is coupled to the container body 2, the first protrusion 31 is in abutting engagement with the interconnection region 503 but not with the second protrusion 32. The first surface 311 of the first protrusion 31 is in abutting engagement with the interconnection region 503 when the door 5 is coupled to the container body 2. By virtue of the third surface 313 and the second surface 312 being coplanar and being spaced apart from the second protrusion 32, when the door 5 is going to be closed during one of the stages of the semiconductor device production process, the tolerance of the engagement between the container body 2 and the door 5 is increased. That is to say, because the first protrusion 31 and the second protrusion 32 are unlikely to be in contact with each other when the door 5 is coupled to the container body 2, likelihood that the second protrusion 32 will hit the first protrusion 31 is greatly reduced. Since the second protrusion 32 is less likely to hit the first protrusion 31, particles (not shown) generated due to abrasion of the surface of any one of the first protrusion 31 and the second protrusion 32 will be greatly reduced. Consequently, it is less likely to trigger alarm caused by the misalignment between the container body 2 and the door 5 in the semiconductor device production process and the transportation of the semiconductor wafers may proceed more smoothly.

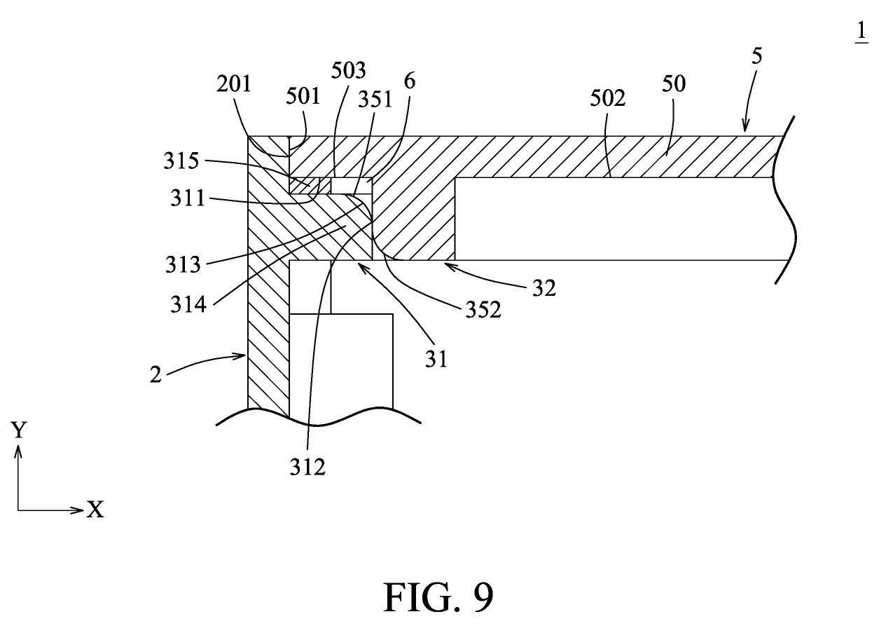

FIG. 9 is a fragmentary, enlarged, schematic sectional view illustrating the engagement between the door 5 and the container body 2 of the wafer transportation container 1 in accordance with some embodiments. The container body 2 shown in FIG. 9 has a structure similar to that of the container body 2 shown in each of FIGS. 5 to 8, but has a difference in the first protrusion 31. Referring to FIG. 9, the first protrusion 31 includes a base portion 314 and a washer portion 315. The base portion 314 has the second surface 312 and the third surface 313 of the first protrusion 31. The washer portion 315 is disposed on and attached to the base portion 314 to serve as the first surface 311 of the first protrusion 31. A hardness of the base portion 314 is higher than a hardness of the washer portion 315. The washer portion 315 is made of a material more deformable than a material of the base portion 314. In some embodiments, the washer portion 315 may include or be made of polymer, a plastic material, other suitable materials with hardness lower than the hardness of the base portion 314, or combinations thereof. Other relatively soft or deformable materials suitable for the washer portion 315 are within the contemplated scope of the present disclosure. When the door 5 is coupled to the container body 2, the washer portion 315 is in abutting engagement with the interconnection region 503 of the door body 50. It is noted that, in some embodiments, as shown in FIG. 9, the third surface 313 of the first protrusion 31 is circularly curved, and the first protrusion 31 is in abutting engagement with the second protrusion 32 when the door 5 is coupled to the container body 2. In some embodiments, in which the first protrusion 31 includes the base portion 314 and the washer portion 315, the third surface 313 may be flat, or just curved, or coplanar with the second surface 312, and the first protrusion 31 may be spaced apart from the second protrusion 32 when the door 5 is coupled to the container body 2. Other suitable geometric shapes for the first protrusion 31 are within the contemplated scope of the present disclosure.

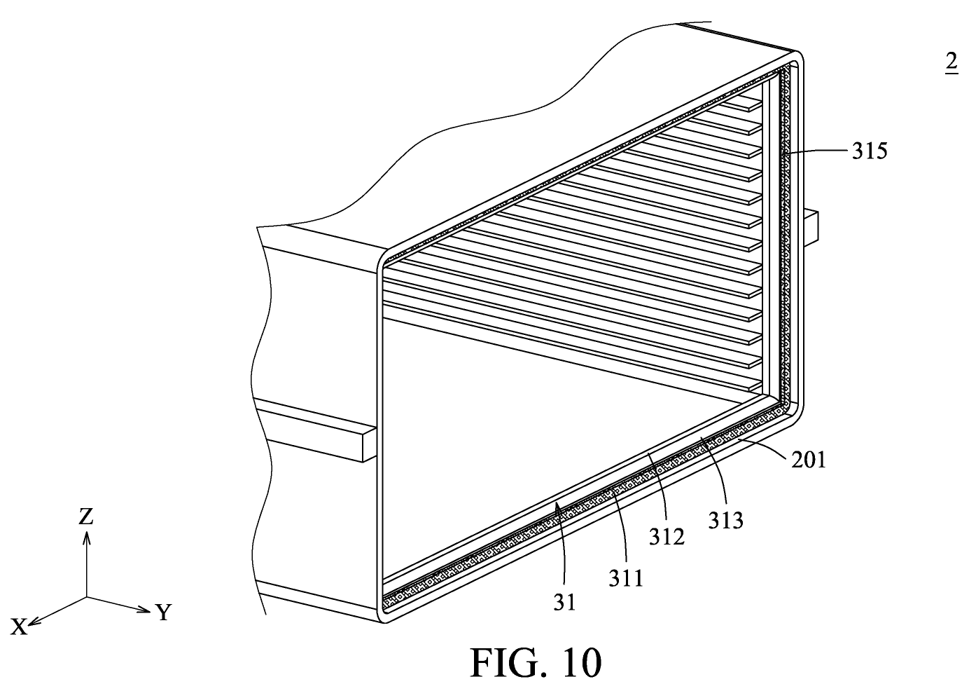

FIG. 10 is a fragmentary, enlarged schematic perspective view illustrating the container body 2 shown in FIG. 9 in accordance with some embodiments. The washer portion 315 of the first protrusion 31 extends along the inner peripheral edge 201 to have a looped shape. In some other embodiments not shown, the washer portion 315 may have a plurality of regions spaced apart from each other along the inner peripheral edge 201. By virtue of the hardness of the base portion 314 being higher than the hardness of the washer portion 315, and by virtue of the washer portion 315 being in abutting engagement with the interconnection region 503 when the door 5 is coupled to the container body 2, even when the container body 2 and the door 5 are misaligned with each other and hit each other during the movement of the door 5 toward the container body 2, shock caused by the hit between the door 5 and the container body 2 may be absorbed by the washer portion 315. Consequently, it is less likely to generate particles (not shown) in the semiconductor device production process.

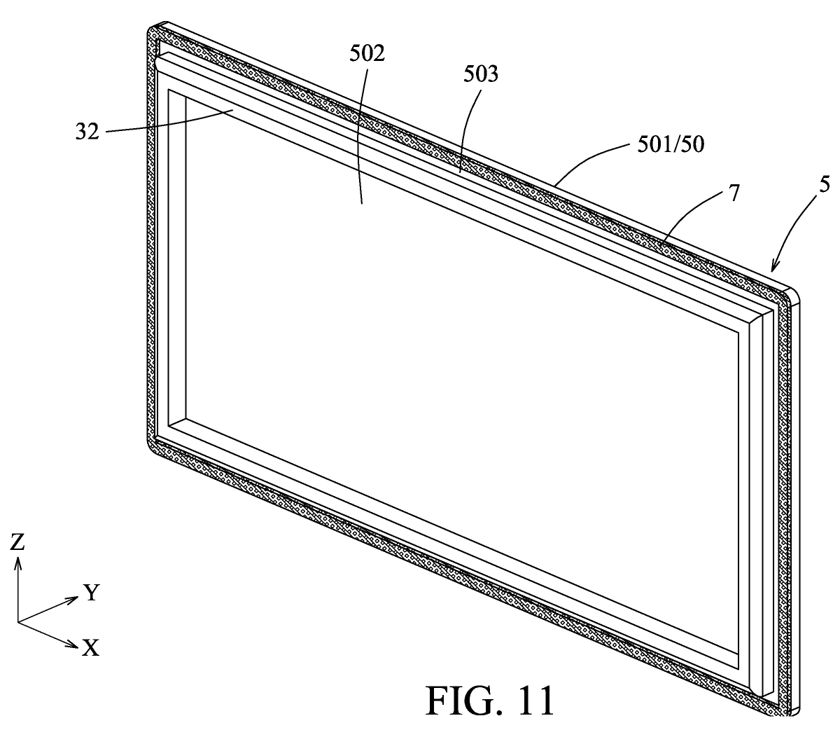

FIG. 11 a schematic perspective view illustrating the door 5 in accordance with some embodiments. Referring to FIG. 11, a surrounding washer 7 is disposed on and attached to the interconnection region 503 of the door 5. Therefore, when the door 5 shown in FIG. 11 is coupled to the container body 2 shown in FIG. 10, the surrounding washer 7 is brought into contact with the washer portion 315, and the first protrusion 31 is in abutting engagement with the interconnection region 503 through the surrounding washer 7. In some embodiments, the door 5 shown in FIG. 11 may be coupled to the container body 2 shown in FIG. 2. In such case, the engagement between the door 5 and the container body 2 may be similar to that shown in FIG. 9, but the surrounding washer 7 is located at the position of the washer portion 315 and the first protrusion 31 does not include the washer portion 315. Thus, when the door 5 shown in FIG. 11 is coupled to the container body 2 shown in FIG. 2, the first surface 311 of the first protrusion 31 is in abutting engagement with the surrounding washer 7 and spaced apart from the interconnection region 503 by the surrounding washer 7. In some embodiments, the surrounding washer 7 may include or be made of polymer, a plastic material, other suitable materials with hardness lower than a hardness of the first protrusion 31, the hardness of the base portion 314, or a hardness of the door body 50, or combinations thereof. Other relatively soft or deformable materials suitable for the surrounding washer 7 are within the contemplated scope of the present disclosure. The surrounding washer 7 extends along the second protrusion 32 to have a looped shape. In some other embodiments not shown, the surrounding washer 7 may have a plurality of regions spaced apart from each other along the second protrusion 32. With the provision of the surrounding washer 7, the first protrusion 31 is in abutting engagement with the interconnection region 503 through the surrounding washer 7 when the door 5 is coupled to the container body 2. As such, even when the container body 2 and the door 5 are misaligned with each other and hit each other during the movement of the door 5 toward the container body 2, the shock caused by the hit between the door 5 and the container body 2 may be absorbed by the surrounding washer 7. Consequently, particles (not shown) generated due to the abrasion of the surface of any one of the first protrusion 31 and the second protrusion 32 will be greatly reduced, and damage to any one of the first protrusion 31 and the second protrusion 32 is greatly alleviated.

In summary, by forming the first cutout portion 351 on the first protrusion 31, the gap 6 is formed among the first protrusion 31, the second protrusion 32 and the interconnection region 503. Accordingly, the tolerance of the engagement between the container body 2 and the door 5 is increased (i.e., the second protrusion 32 may not directly strike the first protrusion 31). In addition, the second protrusion 32 can be guided by the third surface 313 even if the container body 2 and the door 5 are misaligned and come into contact with each other so that the container body 2 and the door 5 can be fittingly coupled eventually. By making the third surface 313 and the second surface 312 of the first protrusion 31 be spaced apart from the second protrusion 32, the likelihood that the second protrusion 32 will hit the first protrusion 31 is greatly reduced. By virtue of the washer portion 315 and/or the surrounding washer 7 absorbing the shock that is caused by the hit between the door 5 and the container body 2, particles (not shown) generated due to the abrasion of the surface of any one of the first protrusion 31 and the second protrusion 32 will be greatly reduced, and the damage to any one of the first protrusion 31 and the second protrusion 32 can be greatly alleviated.

In accordance with some embodiments of the present disclosure, a wafer transportation container includes a container body and a door. The container body has an inner space for accommodation of wafers, an opening configured to allow passage of the wafers into or out of the inner space, an inner peripheral edge disposed along a perimeter of the opening, and a first protrusion formed immediately inwardly of the inner peripheral edge. The door is removably coupled to the container body, and includes a door body having an outer peripheral edge, and an inward surface for confronting the inner space, and a second protrusion formed on the inward surface of the door body. The inward surface has an interconnection region between the second protrusion and the outer peripheral edge of the door body. When the door is coupled to the container body, the outer peripheral edge of the door body is in sealing engagement with the inner peripheral edge of the container body, the first protrusion is in abutting engagement with at least one of the interconnection region and the second protrusion, and a gap is formed among the first protrusion, the second protrusion and the interconnection region.

In accordance with some embodiments of the present disclosure, the first protrusion has a first surface configured to confront the interconnection region when the door is coupled to the container body, a second surface configured to confront the second protrusion when the door is coupled to the container body, and a third surface interconnecting the first surface and the second surface, and configured to border the gap when the door is coupled to the container body.

In accordance with some embodiments of the present disclosure, the first surface is in abutting engagement with the interconnection region when the door is coupled to the container body.

In accordance with some embodiments of the present disclosure, the first protrusion includes a base portion having the second surface and the third surface, and a washer portion disposed on the base portion to serve as the first surface of the first protrusion. A hardness of the base portion is higher than a hardness of the washer portion.

In accordance with some embodiments of the present disclosure, when the door is coupled to the container body, the second surface is in abutting engagement with the second protrusion.

In accordance with some embodiments of the present disclosure, when the door is coupled to the container body, the third surface is spaced apart from the second protrusion by the gap.

In accordance with some embodiments of the present disclosure, when the door is coupled to the container body, the second surface is in abutting engagement with the second protrusion.

In accordance with some embodiments of the present disclosure, when the door is coupled to the container body, the first surface is spaced apart from the interconnection region.

In accordance with some embodiments of the present disclosure, the third surface is curved.

In accordance with some embodiments of the present disclosure, the third surface is circularly curved.

In accordance with some embodiments of the present disclosure, a radius of curvature of the third surface is greater than 1 millimeter and not greater than 10 millimeters.

In accordance with some embodiments of the present disclosure, the third surface is a flat surface arranged inclined with respect to both the first surface and the second surface.

In accordance with some embodiments of the present disclosure, a wafer transportation container includes a container body and a door. The container body has an inner space for accommodation of wafers, an opening configured to allow passage of the wafers into or out of the inner space, an inner peripheral edge disposed along a perimeter of the opening, and a first protrusion formed immediately inwardly of the inner peripheral edge. The door is removably coupled to the container body, and includes a door body having an outer peripheral edge, and an inward surface for confronting the inner space, and a second protrusion formed on the inward surface of the door body. The inward surface has an interconnection region between the second protrusion and the outer peripheral edge of the door body. At least one of the first protrusion and the second protrusion has a cutout portion. When the door is coupled to the container body, the outer peripheral edge of the door body is in sealing engagement with the inner peripheral edge of the container body, the first protrusion is in abutting engagement with at least one of the interconnection region and the second protrusion, and a gap is formed among the first protrusion, the second protrusion and the interconnection region.

In accordance with some embodiments of the present disclosure, the wafer transportation container further includes a surrounding washer disposed on the interconnection region, so that when the door is coupled to the container body, the first protrusion is in abutting engagement with the interconnection region through the surrounding washer.

In accordance with some embodiments of the present disclosure, the cutout portion is formed on the first protrusion such that when the door is coupled to the container body, the first protrusion has a curved corner confronting a corner between the interconnection region and the second protrusion.

In accordance with some embodiments of the present disclosure, the cutout portion is formed on the first protrusion such that when the door is coupled to the container body, the first protrusion has a truncated corner confronting a corner between the interconnection region and the second protrusion.

In accordance with some embodiments of the present disclosure, the cutout portion is formed on the second protrusion such that when the door is coupled to the container body, the second protrusion has a curved corner which is opposite to a corner between the interconnection region and the second protrusion, and which confronts the first protrusion.

In accordance with some embodiments of the present disclosure, when the door is coupled to the container body, the first protrusion is spaced apart from the second protrusion by the gap.

In accordance with some embodiments of the present disclosure, a wafer transportation container includes a container body and a door. The container body has an inner space for accommodation of wafers, an opening configured to allow passage of the wafers into or out of the inner space, an inner peripheral edge disposed along a perimeter of the opening, and a first protrusion formed immediately inwardly of the inner peripheral edge. The door is removably coupled to the container body, and includes a door body having an outer peripheral edge, and an inward surface for confronting the inner space, and a second protrusion formed on the inward surface of the door body. The inward surface has an interconnection region between the second protrusion and the outer peripheral edge of the door body. In response to movement of the door toward the container body, the second protrusion is guided by the first protrusion to bring the outer peripheral edge of the door body into sealing engagement with the inner peripheral edge of the container body.

In accordance with some embodiments of the present disclosure, the first protrusion has a proximal corner and a distal corner which confront the second protrusion when the door is coupled to the container body. The proximal corner and the distal corner are respectively proximal to and distal to the door when the door is coupled to the container body. The second protrusion has a first corner defined with the interconnection region, and a second corner opposite to the first corner. The first corner and the second corner confront the first protrusion when the door is coupled to the container body. In response to movement of the door toward the container body, the second corner is guided by the proximal corner to bring the outer peripheral edge of the door body into sealing engagement with the inner peripheral edge of the container body. When the door is coupled to the container body, the first protrusion is in abutting engagement with the second protrusion, the proximal corner is spaced apart from the second protrusion, and the second corner is spaced apart from the first protrusion.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A wafer transportation container comprising:
a container body having an inner space for accommodation of wafers,
an opening configured to allow passage of the wafers into or out of the inner space,
an inner peripheral edge disposed along a perimeter of the opening, and
a first protrusion formed immediately inwardly of the inner peripheral edge; and
a door removably coupled to the container body, and including a door body having an outer peripheral edge, and an inward surface for confronting the inner space, and
a second protrusion formed on the inward surface of the door body, the inward surface having an interconnection region between the second protrusion and the outer peripheral edge of the door body,
wherein when the door is coupled to the container body, the outer peripheral edge of the door body is in sealing engagement with the inner peripheral edge of the container body, the first protrusion is in abutting engagement with at least one of the interconnection region and the second protrusion, and a gap is formed among the first protrusion, the second protrusion and the interconnection region.

2. The wafer transportation container as claimed in claim 1, wherein the first protrusion has
a first surface configured to confront the interconnection region when the door is coupled to the container body,
a second surface configured to confront the second protrusion when the door is coupled to the container body, and
a third surface interconnecting the first surface and the second surface, and configured to border the gap when the door is coupled to the container body.

3. The wafer transportation container as claimed in claim 2, wherein the first surface is in abutting engagement with the interconnection region when the door is coupled to the container body.

4. The wafer transportation container as claimed in claim 3,
wherein the first protrusion includes
a base portion having the second surface and the third surface, and
a washer portion disposed on the base portion to serve as the first surface of the first protrusion, a hardness of the base portion being higher than a hardness of the washer portion.

5. The wafer transportation container as claimed in claim 3, wherein when the door is coupled to the container body, the second surface is in abutting engagement with the second protrusion.

6. The wafer transportation container as claimed in claim 3, wherein when the door is coupled to the container body, the third surface is spaced apart from the second protrusion by the gap.

7. The wafer transportation container as claimed in claim 2, wherein when the door is coupled to the container body, the second surface is in abutting engagement with the second protrusion.

8. The wafer transportation container as claimed in claim 7, wherein when the door is coupled to the container body, the first surface is spaced apart from the interconnection region.

9. The wafer transportation container as claimed in claim 2, wherein the third surface is curved.

10. The wafer transportation container as claimed in claim 2, wherein the third surface is circularly curved.

11. The wafer transportation container as claimed in claim 10, wherein a radius of curvature of the third surface is greater than 1 millimeter and not greater than 10 millimeters.

12. The wafer transportation container as claimed in claim 2, wherein the third surface is a flat surface arranged inclined with respect to both the first surface and the second surface.

13. A wafer transportation container comprising:
a container body having
an inner space for accommodation of wafers,
an opening configured to allow passage of the wafers into or out of the inner space,
an inner peripheral edge disposed along a perimeter of the opening, and
a first protrusion formed immediately inwardly of the inner peripheral edge; and
a door removably coupled to the container body, and including a door body having an outer peripheral edge, and an inward surface for confronting the inner space, and
a second protrusion formed on the inward surface of the door body, the inward surface having an interconnection region between the second protrusion and the outer peripheral edge of the door body,
wherein at least one of the first protrusion and the second protrusion has a cutout portion, and when the door is coupled to the container body, the outer peripheral edge of the door body is in sealing engagement with the inner peripheral edge of the container body, the first protrusion is in abutting engagement with at least one of the interconnection region and the second protrusion, and a gap is formed among the first protrusion, the second protrusion and the interconnection region.

14. The wafer transportation container as claimed in claim 13, further comprising a surrounding washer disposed on the interconnection region, so that when the door is coupled to the container body, the first protrusion is in abutting engagement with the interconnection region through the surrounding washer.

15. The wafer transportation container as claimed in claim 13, wherein the cutout portion is formed on the first protrusion such that when the door is coupled to the container body, the first protrusion has a curved corner confronting a corner between the interconnection region and the second protrusion.

16. The wafer transportation container as claimed in claim 13, wherein the cutout portion is formed on the first protrusion such that when the door is coupled to the container body, the first protrusion has a truncated corner confronting a corner between the interconnection region and the second protrusion.

17. The wafer transportation container as claimed in claim 13, wherein the cutout portion is formed on the second protrusion such that when the door is coupled to the container body, the second protrusion has a curved corner which is opposite to a corner between the interconnection region and the second protrusion, and which confronts the first protrusion.

18. The wafer transportation container as claimed in claim 13, wherein when the door is coupled to the container body, the first protrusion is spaced apart from the second protrusion by the gap.

19. A wafer transportation container comprising:
a container body having
an inner space for accommodation of wafers,
an opening configured to allow passage of the wafers into or out of the inner space,
an inner peripheral edge disposed along a perimeter of the opening, and
a first protrusion formed immediately inwardly of the inner peripheral edge; and
a door removably coupled to the container body, and including a door body having an outer peripheral edge, and an inward surface for confronting the inner space, and
a second protrusion formed on the inward surface of the door body, the inward surface having an interconnection region between the second protrusion and the outer peripheral edge of the door body,
wherein when the door is coupled to the container body, the outer peripheral edge of the door body is in sealing engagement with the inner peripheral edge of the container body, the first protrusion is in abutting engagement with at least one of the interconnection region and the second protrusion, and a gap is formed among the first protrusion, the second protrusion and the interconnection region, and
wherein in response to movement of the door toward the container body, the second protrusion is guided by the first protrusion to bring the outer peripheral edge of the door body into sealing engagement with the inner peripheral edge of the container body.

20. The wafer transportation container as claimed in claim 19, wherein:
the first protrusion has a proximal corner and a distal corner which confront the second protrusion when the door is coupled to the container body, the proximal corner and the distal corner being respectively proximal to and distal to the door when the door is coupled to the container body;
the second protrusion has a first corner defined with the interconnection region, and a second corner opposite to the first corner, the first corner and the second corner confronting the first protrusion when the door is coupled to the container body;
in response to movement of the door toward the container body, the second corner is guided by the proximal corner to bring the outer peripheral edge of the door body into sealing engagement with the inner peripheral edge of the container body; and
when the door is coupled to the container body, the first protrusion is in abutting engagement with the second protrusion, the proximal corner is spaced apart from the second protrusion, and the second corner is spaced apart from the first protrusion.
